(19) United States
(12) Patent Application Publication
(10) Pub. No.: US 2026/0122908 A1
(43) Pub. Date: Apr. 30, 2026

(54) ARRAY INCLUDING A PLURALITY OF NON-VOLATILE MEMORY CELLS

(71) Applicant: COMMISSARIAT A L’ENERGIE ATOMIQUE ET AUX ENERGIES ALTERNATIVES, PARIS (FR)

(72) Inventors: Laurent GRENOUILLET, GRENOBLE CEDEX 09 (FR); Jean COIGNUS, GRENOBLE CEDEX 09 (FR); Simon MARTIN, GRENOBLE CEDEX 09 (FR)

(21) Appl. No.: 19/151,215

(22) PCT Filed: Jan. 25, 2024
(86) PCT No.: PCT/EP2024/051819

§ 371 Date: Jul. 25, 2025

(30) Foreign Application Priority Data
Jan. 27, 2023 (FR) FR2300795

(51) Int. Cl. H10B 51/30; H10D 30/69; H10D 64/68

(52) U.S. Cl. CPC H10B 51/30; H10D 30/701; H10D 64/689

(57) ABSTRACT

A memory array includes a plurality of memory cells including a first electrode, a second electrode and a layer of crystalline active material disposed between the first electrode and the second electrode and having a thickness of between 2 nm and 20 nm, the active material being either hafnium dioxide doped with a doping element selected from one of the following elements: Si, Al, Zr, Gd, Ge, Y or N, or an alloy HfₓZr₁₋ₓO₂ undoped or doped with a doping element selected from one of the following elements: Si, Al, Gd, Ge, Y or N, with 0<x<1; the first or second electrodes being formed of at least two layers including a first conductive layer in contact with the layer of active material and selected to create oxygen vacancies in the layer of active material and a second conductive layer disposed on the first conductive layer.

### TECHNICAL FIELD

The present invention relates to an array including a plurality of non-volatile memory cells of the OxRAM and FeRAM type.

### TECHNOLOGICAL BACKGROUND OF THE INVENTION

For applications that require information storage even when power is turned off, non-volatile EEPROM or FLASH memories are conventionally used.

Other emerging types of non-volatile memories based on active materials such as ferroelectric materials (FeRAM memories) or materials such as oxides (OxRAM memories) are a promising alternative to FLASH or EEPROM type memories. These memories are generally combined in the form of an array integrating a plurality of memory cells, for example defined by a 1T1R architecture (one selection transistor in series with one memory).

OxRAM, which stand for “Oxide Resistive RAM”, memories are non-volatile resistive memories. These memories can have at least two resistive states, corresponding to a High Resistance State (HRS) and a Low Resistance State (LRS), when a voltage is applied. OxRAM memories have an M-I-M (Metal-Insulator-Metal) structure comprising an active material with variable electrical resistance, generally a transition metal oxide (e.g. WO₃, HfO₂, Ta₂O₅, TiO₂ . . . ), disposed between two metal electrodes. One of the two electrodes often includes a layer, for example of Ti, having the feature of being an “oxygen scavenging layer”, i.e. a layer for creating oxygen vacancies in the hafnium dioxide-based active layer of the OxRAM when this conductive layer is in contact with the active layer of the OxRAM. The transition from the “HRS” state to the “LRS” state is indeed governed by the formation and rupture of a conductive filament between the two electrodes. This conductive filament is created by the presence of oxygen vacancies present in the active layer of the memory. By modifying the potentials applied to the electrodes, it is possible to modify distribution of the filament and thus modify electrical conduction between the two electrodes. In the active layer, the electrically conductive filament is either broken or otherwise reformed to vary the resistance level of the memory cell during write cycles and then reset cycles (SET operations, when the filament is reformed, resulting in the LRS state, and RESET operations, resulting in the HRS state, when the filament is broken again by applying a SET voltage, V_{SET} or RESET voltage, V_{RESET} across the electrodes). The manufacture of a filamentary memory comprises a so-called “forming” step, during which the filament is formed for the first time in the active layer, which is initially devoid of filament. The active layer is indeed initially completely electrically insulating. During the initial “forming” step, an electrically conductive filament is formed in the active layer by causing a kind of controlled breakdown of this layer. The filament thus formed then extends all over through the active layer, electrically connecting the bottom electrode and the top electrode. To carry out this forming step, an electrical voltage can, for example, be applied between the bottom electrode and the top electrode of the memory cell in question, then gradually increased to a threshold voltage, called the forming voltage V_{forming}, above which breakdown of the active layer is achieved. After this “forming” step, the memory cell is ready for use. The conductive filament can then be broken, and then reformed, then broken again, and so on, at a voltage value lower than the forming voltage V_{forming}.

The main advantages of OxRAM memories are that they are non-volatile, i.e. they retain stored information even when power is turned off, they have low write and read times compared to other types of non-volatile memories such as FLASH memories, can be integrated into chips on a large scale due to their reduced spatial dimensions and active layers of low thickness, and allow back-end integration compatible with CMOS technology.

However, OxRAM resistive memories still have some properties that need to be improved.

It would thus be especially desirable to increase the memory window of OxRAM memories. The memory window of an OxRAM memory is defined as a range of resistance values between two bounds. The lower bound is the highest resistance value among the resistances of the LRS on-states. The upper bound is the lowest resistance value among the resistances of the HRS off-states. A narrow memory window is therefore associated with off-states and on-states with closely spaced resistance values, which leads to reliability problems in OxRAM resistive memory cells.

In addition, the write and erase endurance of OxRAM memories is quite limited (in the order of 10⁴-10⁵ cycles).

OxRAM memories additionally have relatively high forming voltages as well as relatively high variability within the resistance values in the LRS and HRS states.

Finally, it would also be desirable to reduce the compliance current of OxRAM memories. For the record, the compliance current is the current intensity value set via a selection transistor in series with the OxRAM memory, which limits the maximum current allowed to flow through the memory in order not to deteriorate it. In order to use the lowest possible resistance value, a sufficient compliance current must be available to achieve a sufficiently low on-state resistance value. A high compliance current level requires the use of bulky selection transistors, which limits integration density and on the other hand reduces the lifetime of the memory points. Thus, reducing the compliance current reduces the space footprint of the selection transistor and consequently that of the entire 1T-1R cell.

It is known that variability of OxRAM memories can be improved by using an active material with variable electrical resistance that is amorphous rather than crystalline, for example amorphous HfO₂.

It is also known that reduction in the forming voltage of OxRAM memories can be achieved by a step of ionically implanting silicon into the active layer, for example of HfO₂, in order to obtain a doped active layer. The implantation doses are in the order of 3 to 4.10¹⁵ cm⁻² with an implantation energy of between 2 keV and 4 keV in order to have 4 to 5% silicon present in the active layer with a thickness of between 5 and 10 nm.

It is understood from the above that a person skilled in the art wishing to produce an OxRAM memory with good properties will use an amorphous HfO₂ active layer implanted with silicon at high doses (i.e. greater than or equal to 3.10¹⁵ cm⁻²).

The main qualities of ferroelectric memories or FeRAM memories are that they are non-volatile, i.e. they retain stored information even when power is turned off, consume little energy, have low write and read times compared to other types of non-volatile memories such as FLASH memories, have excellent temperature stability and allow back-end integration compatible with CMOS technology.

Like OxRAM memories, FeRAM memories have an M-I-M (Metal-Insulator-Metal) structure comprising an active material with variable electrical resistance, for example HfO₂ arranged between two metal electrodes, for example of TiN. Hafnium dioxide is used here in its orthorhombic phase, which gives it ferroelectric properties: it is known that this crystallisation in the orthorhombic phase is achieved by implanting, for example Si, into the active layer, with a dose in the order of 3.10¹⁴ cm⁻² with an implantation energy of around 4 keV, i.e. typically 10 times less silicon dopants than those used in OxRAM type memory.

Ferroelectric memories are capacitive type memories with two states of remanent polarisation, +Pr and −Pr. [FIG. 1] illustrates the operation of ferroelectric memories. This is based on ferroelectric properties of their active material placed between two electrodes. By applying a potential difference between the two electrodes, creating an electric field with a value greater than the positive coercive field +Ec, the ferroelectric memory is placed in a high remanent polarisation state +Pr, and by applying a potential difference creating an electric field with a value less than the negative coercive field −Ec, the ferroelectric memory is placed in a low remanent polarisation state −Pr. The high remanent polarisation state +Pr then corresponds to the binary logic state ‘0’ and the low remanent polarisation state −Pr to the binary logic state ‘1’, which allows information to be stored. It will be noted that when the potential difference is no longer applied, the remanent polarisation state remains: this explains the non-volatile nature of ferroelectric memories. When reading a ferroelectric memory, it is not known in advance what polarisation state the memory is in. Therefore, for reading, it is assumed to be in a given state and a voltage, for example positive, is applied beyond the voltage creating an electric field with a value greater than the positive coercive field +Ec: if the memory was already in the high remanent polarisation state +Pr, this polarisation state does not change and no current peak will be observed (or a very low current peak will be observed). Conversely, if the memory was in the low remanent polarisation state −Pr, a much higher current peak would be observed. The consequence of this read operation is that it destroys the polarisation state.

It may additionally be useful to have OxRAM and FeRAM memories co-integrated on a same array due to the limitations of FeRAM in read mode and OxRAM in write mode.

### SUMMARY OF THE INVENTION

The invention provides a solution to the problems previously discussed by providing an array of memory cells, said cells having improved OxRAM-type operation, especially in terms of increased memory window and lower compliance current.

To this end, one object of the invention is especially a memory array comprising a plurality of memory cells of a first type, said array not including any memory cells of a type other than the first type, each of said memory cells of the first type comprising a first electrode, a second electrode and a layer of crystalline active material disposed between the first electrode and the second electrode, the layer of active material having a thickness of between 2 nm and 20 nm, the active material being:
either hafnium dioxide doped with a doping element selected from one of the following elements: Si, Al, Zr, Gd, Ge, Y or N;
or an alloy HfₓZr₁₋ₓO₂, undoped or doped with a doping element selected from one of the following elements: Si, Al, Gd, Ge, Y or N, with 0<x<1;
   at least one of said first and second electrodes being formed of at least two layers including:
a first conductive layer in contact with the layer of active material and selected to create oxygen vacancies in the layer of active material;
a second conductive layer disposed on the first conductive layer.

Memory cells of a first type are understood to be a set of cells that are identical in terms of the layers forming their stack, the materials of these layers and the thicknesses of these layers measured along the axis perpendicular to the plane of the layers; cells of a first type may, however, have different lateral dimensions or even different shapes.

By virtue of the invention, the particular structure of the memory cells makes it possible to obtain an array of cells that function both as FeRAM and as OxRAM, despite having an identical structure.

In other words, each memory cell in the array functions both:
as a filament-type resistive memory (OxRAM) via SET operations, when the filament is formed resulting in an LRS state, and RESET operations resulting in the HRS state, when the filament is broken, by applying a SET voltage, V_{SET}, or a RESET voltage, V_{RESET} across the electrodes;
as a capacitive memory (FeRAM) via the application of a potential difference between the two electrodes creating an electric field with a value greater than the positive coercive field +Ec, the ferroelectric memory being placed in a high remanent polarisation state +Pr and by applying a potential difference creating an electric field with a value less than the negative coercive field −Ec, the ferroelectric memory being placed in a low remanent polarisation state −Pr. The presence of the first conductive layer chosen to create oxygen vacancies in the layer of active material might lead the skilled person to believe that the cells operate exclusively in a filamentary mode; surprisingly, the inventors realised that the cells could also exhibit ferroelectric behaviour.

Surprisingly, the inventors thus realised that an identical active layer for memory cells could be used to achieve both the ferroelectric effect of a FeRAM and the resistive memory effect of an OxRAM. Thus, doping of the active layer with hafnium dioxide required for FeRAM also ensures the resistive operation of OxRAM. The same reasoning applies to an active layer formed by a HfZrO₂ alloy: in the case of HfZrO₂, the ternary alloy HfZrO₂ does not necessarily require doping of the active layer.

In addition, each memory cell of the array according to the invention has improved OxRAM operation compared to known OxRAM cells. The combination of an active layer of relatively low thickness (i.e. between 2 and 10 nm) and an oxygen scavenging layer in contact with the active layer promotes crystallisation of the active layer in its orthorhombic or tetragonal phase. Surprisingly, this crystallisation does not impair the operation of the OxRAM memory, for which the skilled person usually uses amorphous or monoclinic HfO₂. On the contrary, the configuration of each cell according to the invention makes it possible to obtain memory windows that increase with memory cycling, especially compared to an amorphous material in the active layer, as well as operation at a lower compliance current (again compared to an active layer made of amorphous material): this lower compliance current allows for lower power consumption and thus a smaller 1T-1R cell size.

Finally, each memory cell of the array according to the invention has improved FeRAM operation. The addition of an “oxygen scavenging layer” “(first conductive layer of electrode) between the active layer and the second conductive layer of electrode increases the value of the remanent polarisation of the ferroelectric active layer (orthorhombic crystallisation) in the virgin state as well as the maximum polarisation during cell cycling. Similarly, the addition of this layer significantly increases the memory window of the FeRAM and reduces the programming/read voltages.

In addition to the characteristics just discussed in the previous paragraph, the array according to the invention may have one or more of the following additional characteristics, considered individually or according to any technically possible combinations:
In the case of the active material being hafnium dioxide doped with a doping element selected from one of the following elements: Si, Al, Zr, Gd, Ge, Y or N, the doping element is present in a percentage of less than or equal to 2% in the active material relative to the total number of atoms in the active material.
The crystalline layer of active material is crystallised in an orthorhombic or tetragonal phase.
The array according to the invention includes a plurality of first access lines and a plurality of second access lines, each memory cell being located at an intersection between a first access line and a second access line allowing it to be individually addressed.
The thickness of the layer of active material is between 2 and 10 nm and preferably between 4 and 6 nm.
The thickness of the layer of active material is substantially equal to 5 nm.
The doping element is silicon implanted into the layer of active material and the implantation dose of Si into the layer of active material is between 2.10¹⁴ cm⁻² and 5.10¹⁴ cm⁻².
The conductive material of the second conductive layer is selected from the following materials: TIN, TaN or W.
The conductive material of the first conductive layer is Ti or Hf when the material of the second conductive layer is TIN or Ta, or Hf when the material of the second conductive layer is TaN or Ti, or Hf or Ta when the material of the second layer is W.
The thickness of the first conductive layer is less than or equal to the thickness of the layer of active material.
The thickness of the first conductive layer is less than or equal to 70% of the thickness of the layer of active material. Preferably, the thickness of the first conductive layer is less than or equal to 50% of the thickness of the layer of active material. Having a first active layer thickness less than 70%, and preferably 50%, of the thickness of the active layer makes it possible to limit the maximum resistance reached by the memory cell.
Each memory cell is connected in series with a selection transistor.
Said selection transistor is chosen to deliver a compliance current through the memory cell with an intensity less than or equal to 150 μA.
The second conductive layer has a thickness of between 10 nm and 200 nm.
The first type of memory cells corresponds to a same nature and a same thickness of layer of active material.
Each memory cell is in series with a transistor or a selector such as a PN diode or an OTS selector. In addition to their role as a selector, the transistor or OTS-type selector or PN diode also protect the memory cell against the risk of breakdown.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 illustrates the operation of a ferroelectric FeRAM memory.

FIG. 2 represents a memory cell used in the array according to the invention.

FIG. 3 represents an array according to the invention including a plurality of memory cells as illustrated in [FIG. 2].

FIG. 4 represents an enlargement of a part of the array of [FIG. 3].

FIG. 5 shows the empirical cumulative distribution function measured on the basis of the resistance value for different arrays, including one according to the invention, and for different cycling patterns.

FIG. 6 shows a TEM image of a memory cell of an array according to the invention.

FIG. 7 shows a measurement of the 2 theta grazing incidence X-ray diffraction intensity on the memory cell imaged in FIG. 6.

FIG. 8 shows a measurement of 2 theta grazing incidence X-ray diffraction intensity on two memory cells, one of which is used in the array according to the invention.

FIG. 9 shows a measurement of 2 theta grazing incidence X-ray diffraction intensity on two memory cells, one of which is used in the array according to the invention with a lower active layer thickness than in the case of the cells in FIG. 8.

FIG. 10 shows a measurement of 2 theta grazing incidence X-ray diffraction intensity on two memory cells, one of which has a highly doped active layer and the other a undoped active layer.

FIG. 11 shows the values of remanent polarisation as a function of cycling for a memory cell operating in FeRAM mode of an array according to the invention and a FeRAM cell of the state of the art;

FIG. 12 shows the course of the memory window measured on a 16-kbit array according to the invention formed by 16,384 FeRAM memory cells.

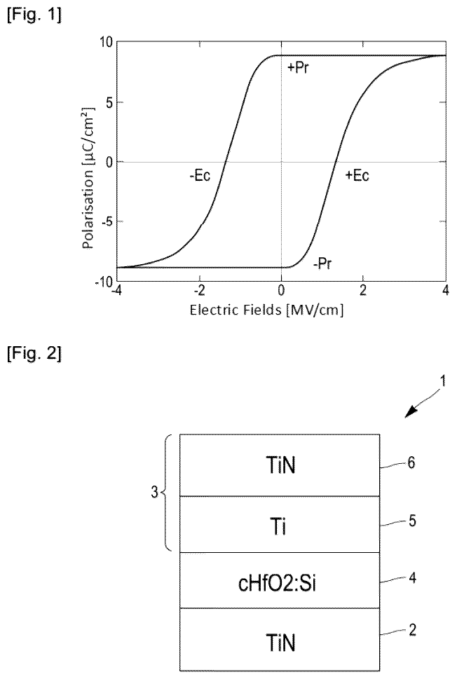

### DETAILED DESCRIPTION OF AT LEAST ONE EMBODIMENT OF THE INVENTION

Unless otherwise specified, a same element appearing in different figures has a single reference.

The invention relates to an array of memory cells that are all identical; in other words, the array according to the invention includes a plurality of identical memory cells without including any other type of memory cell. An example of memory cell 1 included in the array according to the invention is illustrated in FIG. 2.

The memory cell 1 includes a first electrode 2 (referred to as the bottom electrode), a second electrode (referred to as the top electrode) 3 and a layer of active material 4 made of hafnium dioxide HfO₂ disposed between the first electrode 2 and the second electrode 3.

The layer of active material 4 of hafnium dioxide HfO₂ is here made of an active material HfO₂ doped with silicon and crystallised in its orthorhombic or tetragonal phase. The thickness of the layer of active material 4 is between 2 and 10 nm and preferably between 4 and 6 nm (typically in the order of 5 nm).

The active material is made in an orthorhombic or tetragonal crystallisation state. To achieve this, the HfO₂ material is doped with a doping element, which is preferably silicon Si. However, other doping elements such as aluminium Al, zirconium Zr, germanium Ge, gadolinium Gd, yttrium Y or r nitrogen N could also be used. The layer of active material 4 is, for example, exposed to a dopant dose of between 2.10¹⁴ ions/cm² and 5.10¹⁴ ions/cm² corresponding to a dopant element present in a percentage of less than or equal to 2% in the active material relative to the total number of atoms in the active material. It is also possible to use a ternary alloy HfZrO₂ (for example Hf_{0.5}Zr_{0.5}O₂) as the active material, the latter being doped (for example with silicon) or undoped.

The conductive material of the bottom electrode 2 is, for example, titanium nitride TIN. TiN is a non-limiting example, but other conductive materials such as TaN or W could also be used. The thickness of the bottom electrode is, for example, between 10 nm and 200 nm.

The top electrode 3 is formed by a bilayer including a first conductive layer 5 and a second conductive layer 6.

The conductive material of the second conductive layer 6 is also, for example, titanium nitride TIN. TIN is a non-limiting example, but other conductive materials such as TaN or W could also be used. The thickness of the second conductive layer 6 is, for example, between 10 nm and 200 nm.

The first conductive layer 5 is in direct contact with the active layer 4 and has the feature of being an “oxygen scavenging layer”, i.e. a layer for creating oxygen vacancies in the active layer when this second conductive layer is in contact with the active layer. The material of the first conductive layer 5 is, for example, titanium Ti or hafnium when the material of the second conductive layer 6 is TIN. It may also be tantalum Ta or hafnium when the material of the second conductive layer 6 is TaN. It will be noted that Ti (or Ta) is a good bonding material for the upper layer of TiN (or TaN).

The thickness of the first conductive layer 5 is strictly positive and preferably less than or equal to the thickness of the active layer 4. The thickness of the first conductive layer 5 is, for example, substantially equal to the thickness of the active layer 4. The first conductive layer 5 has the advantage of promoting crystallisation of the active layer 4 in its orthorhombic or tetragonal phase, especially with relatively low thicknesses of active layers (i.e. in the order of 5 nm).

As explained above, the cell 1 in FIG. 2 can function both as an OxRAM-type filamentary memory and as a FeRAM-type capacitive memory (ferroelectric if the active layer is crystallised in an orthorhombic state or antiferroelectric if the active layer is crystallised in a tetragonal state).

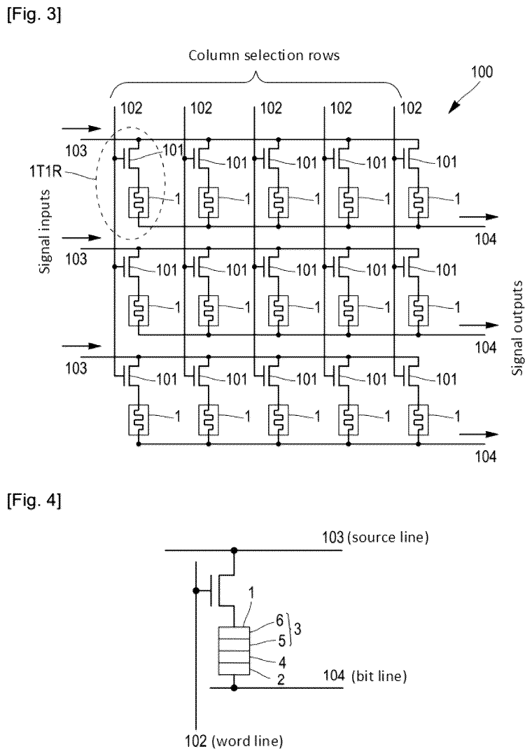

FIG. 3 represents an array 100 according to the invention including a plurality of cells 1 as represented in FIG. 2. The architecture of the array 100 is a 1T1R type architecture (1 selection transistor 101 in series with one memory cell 1). FIG. 4 is an enlargement of the array 100 on a set 1T1R. Here, the top electrode 3 of the cell 1 is connected to the drain of the transistor 101.

The array 100 thus includes a plurality of 1T1R sets disposed respectively in rows and columns.

The array 100 includes a plurality of word lines 102 here represented vertically. Each word line 102 is connected to each gate of a plurality of selection transistors 101 arranged on a same column.

The array 100 also includes a plurality of source lines 103 here represented horizontally. Each source line 103 is connected to each source of the plurality of selection transistors 101 disposed on a same row.

The array 100 also includes a plurality of bit lines 104 represented here horizontally. Each bit line 104 is connected to the bottom electrode 2 of the plurality of cells 1 disposed on a same row.

The array 100 thus includes a plurality of first access lines 103 (source lines) and a plurality of second access lines 104 (bit lines), each memory cell 1 in series with a transistor 101 being located at an intersection between a first access line and a second access line allowing it to be individually addressed, the array further including a plurality of word lines 102 connected to the gates of the transistors 101.

The memory cell 1 to be programmed is selected by activating the transistor 101 by applying a voltage to its gate via the word line and by injecting a desired programming voltage (SET or RESET) via the bit line.

The array 100 of FIG. 3 is represented for purely illustrative purposes, it being understood that other types of array architecture may be contemplated for the invention. In particular, in FIG. 3, the bit lines and the source lines are parallel to each other, but they may also be perpendicular to each other. In this case, the word lines may be parallel to the bit lines. Thus, the array according to the invention could also be an array including a plurality of cells 1 in series with a selector such as a PN diode or an OTS (“Ovonic Threshold Switching”) selector. Similarly, the array according to the invention may be a two-dimensional array or a three-dimensional array.

In order to illustrate the advantages of the array according to the invention in an OxRAM operation, the applicant has made three different 1T1R arrays of 16 kb (i.e. approximately 16384 cells per array):
A first array M1 including OxRAM cells comprising an active layer of undoped amorphous HfO₂ with a thickness of 5 nm with a first conductive layer of Ti with a thickness of 5 nm in contact with the active layer;
A second array M2 according to the invention with both OxRAM and FeRAM cells comprising an active layer of crystallised HfO₂ (orthorhombic or tetragonal) doped with 1% Si (i.e. dopant dose of 2.10¹⁴ ions/cm² with an implantation energy of 2 keV) having a thickness of 5 nm with a first conductive layer of Ti having a thickness of 5 nm in contact with the active layer;
A third array M3 with OxRAM cells including an active layer of amorphous HfO₂ doped with 10% Si (i.e. dopant dose of 2.10¹⁵ ions/cm² with an implantation energy of 2 keV) having a thickness of 5 nm with a first conductive layer of Ti having a thickness of 5 nm in contact with the active layer

It will be noted that the other elements of the cells are identical from one array to another and are formed by:
A first electrode of TiN of the same thickness
A second conductive layer of the second electrode of TIN of the same thickness.

The applicant carried out several cycling operations (a first cycling type corresponding to a series of SET operations and a second cycling type corresponding to a series of RESET operations) under the same conditions on each of the arrays M1, M2 and M3. The series correspond respectively to 10, 100, 1000 and 10⁵ cycles (i.e. SET or RESET writing depending on the first or second cycling type) and have been carried out so as to have a compliance current of around 105 μA when the cells are in a low-resistance state LRS. More generally, the selection device (here the transistor) is dimensioned to provide a compliance current less than or equal to 150 μA.

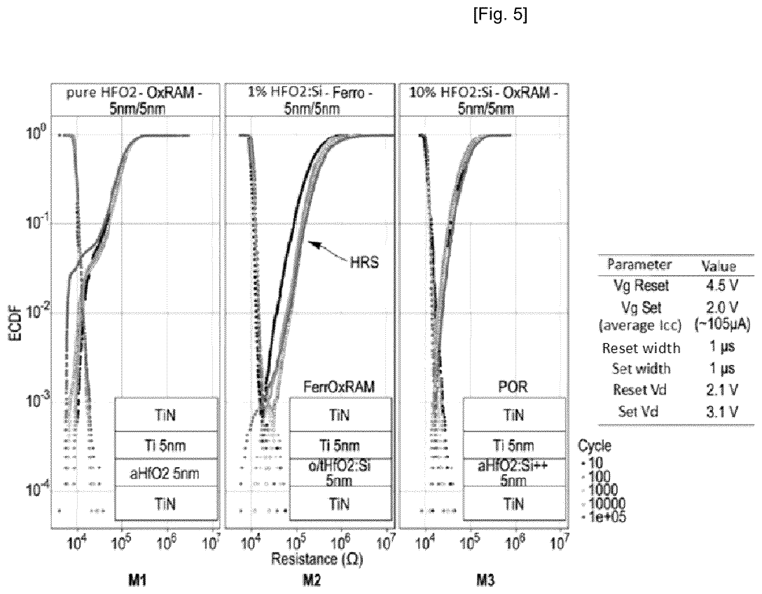

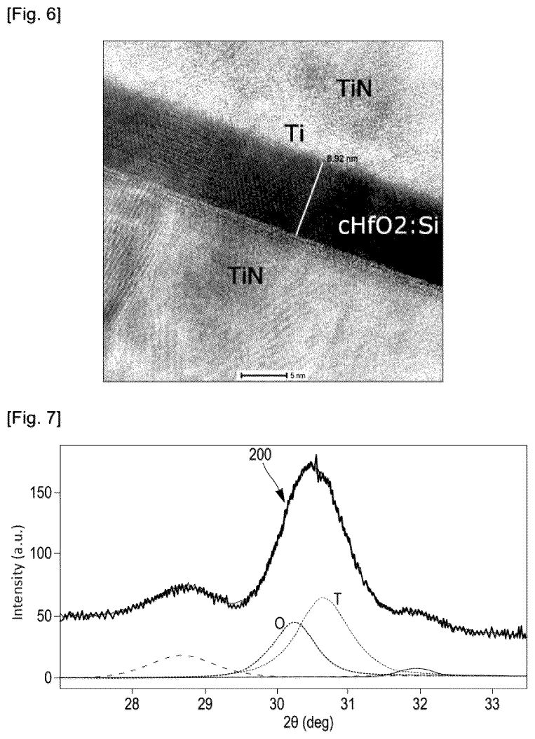

FIG. 5 respectively shows the Empirical Cumulative Distribution Function (ECDF) as a function of the resistance value for arrays M1, M2 and M3 and for the different SET and RESET cycling patterns.

Two important observations can be made from these curves.

Firstly, it is noted that the array M2 according to the invention has far fewer memory points where it is no longer possible to distinguish between the LRS state and the HRS state (case of intersecting curves) than in the case of the arrays M1 and M3. Thus, for low compliance currents (i.e. advantageously less than 150 μA), the performance of the array M2 is much better than that of the arrays M1 and M3. Such a result is particularly interesting when seeking to use smaller selection transistors and therefore smaller overall sizes of 1T1R cells, which de facto leads to lower energy consumption.

In addition, advantageously and unexpectedly, it is observed that the high resistance state HRS drifts towards higher resistance values as the number of cycles increases. Thus, the memory window of the array M2 according to the invention increases with cycling operations, unlike the other arrays M1 and M3.

FIG. 6 shows an image obtained by Transmission Electron Microscopy (TEM) of a memory cell used in an array according to the invention; this image shows an active layer of 8.9 nm of HfO₂ doped with Si (less than 2%) in contact with a layer of Ti, the active zone presenting crystallites in orthorhombic or tetragonal form. This last result is confirmed by the curve represented in FIG. 7 showing measurements 200 of the 2 theta grazing incidence X-ray diffraction intensity. The curve shows a diffraction peak at 30.5°, corresponding to the respective theoretical O and T positions of a crystallised structure in orthorhombic or tetragonal form. It is not possible to distinguish on the curve whether the crystallisation is orthorhombic or tetragonal, insofar as the experimental diffraction peak is too wide and may correspond to either of the theoretical peaks; however, it is clearly apparent from the curve that the active layer is crystallised in orthorhombic (ferroelectric) or tetragonal (antiferroelectric) form.

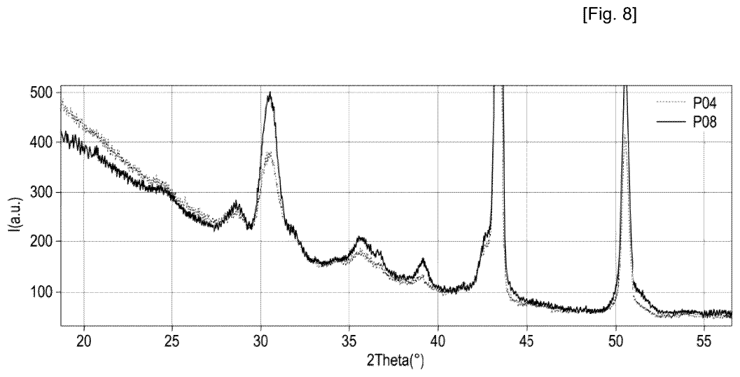

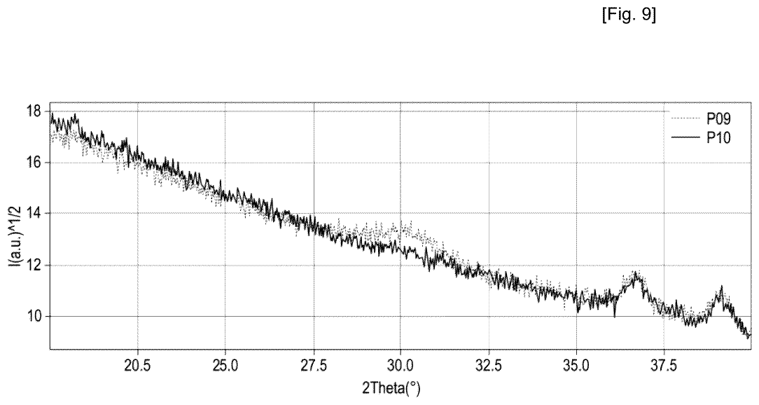

FIG. 8 shows a 2 theta grazing incidence X-ray diffraction intensity measurement on two memory cells:
A first P08 for use in an array according to the invention and including 10 nm of Si-doped HfO₂ (less than 2%) in contact with a Ti layer;
A second P04 including 10 nm of Si-doped HfO₂ (less than 2%) in contact with a TiN layer (and therefore without a Ti layer).

It is noticed in this curve that the presence of the Ti layer creating oxygen vacancies in contact with the active layer promotes crystallisation of the active layer, with the absorption peak at 30.5°, characteristic of orthorhombic or tetragonal crystallisation, being significantly more important in the case of cell P08 than in that of cell P04.

Since the first conductive layer of a material creating oxygen vacancies promotes orthorhombic or tetragonal crystallisation of the active layer, it is thus possible to use lower thicknesses of active layers. This point is illustrated by FIG. 9, which shows a measurement of 2 theta grazing incidence surface diffraction intensity on two memory cells:
A first P10 for use in an array according to the invention and including 5 nm of HfO₂ doped with Si (less than 2%) in contact with a Ti layer;
A second P09 including 5 nm of Si-doped HfO₂ (less than 2%) in contact with a TiN layer (and therefore without a Ti layer).

It is noticed in this curve that the presence of the Ti layer creating oxygen vacancies in contact with the active layer allows crystallisation of the active layer of cell P10 with the presence of the absorption peak at 30.5°, characteristic of orthorhombic or tetragonal crystallisation, this peak being absent in the case of the cell P09.

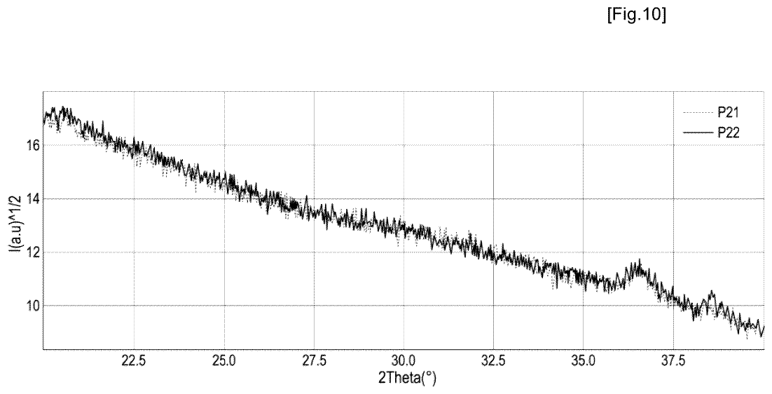

FIG. 10 illustrates the importance of low doping (i.e. less than 2%) of the active layer. In other words, to obtain orthorhombic or tetragonal crystallisation, it is also suitable that doping is neither too high nor absent. This phenomenon is illustrated by FIG. 10, which shows a measurement of 2 theta grazing incidence X-ray diffraction intensity on two memory cells:
A first P21 comprising 10 nm of HfO₂ without doping and in contact with a Ti layer;
A second P22 including 10 nm of HfO₂ doped with 10% Si in contact with a Ti layer.

It is noticed herein that neither curve shows the peak characteristic of an orthorhombic or tetragonal crystallisation. Thus, it is indeed the combination of the presence of the first conductive layer made of a material that creates oxygen vacancies (of Ti, for example) with the low doping of less than 2% of the active layer doped with less than 2% (e.g. Si-doped) that makes it possible to obtain the ad hoc crystallisation effect. In the case of an undoped HfₓZr₁₋ₓO₂ alloy, Zr can be considered to replace the Si doping, so that crystallisation is also achieved.

As has been mentioned above, the array according to the invention includes cells likely to function both as OxRAM and as FeRAM. It has been shown that the performance of cells operating as OxRAM is improved. It will be shown below that the same is true when these cells operate as FeRAM (thus in capacitive mode).

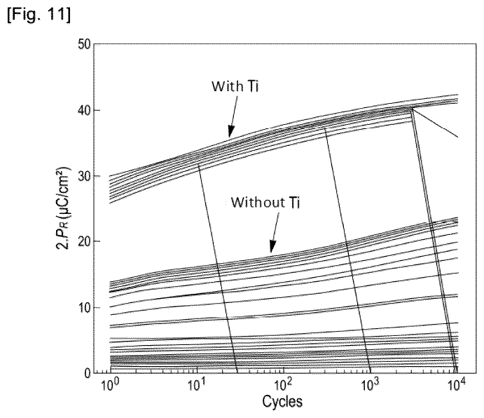

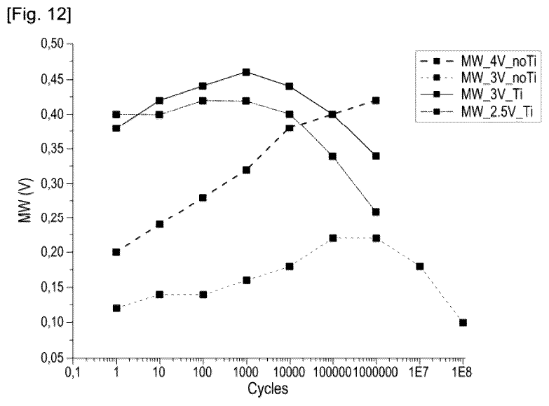

FIG. 11 shows that, all other things being equal, adding a first conductive layer of Ti between the second conductive layer of TIN of the top electrode and the ferroelectric layer of HfO2:Si (here with a thickness of 10 nm) increases the value of the remanent polarisation of the ferroelectric layer in the virgin state, and the maximum polarisation during cycling.

The measurements are taken on a 200 mm plate, on backend-integrated ferroelectric capacitor cells (FeRAM). The addition of Ti also reduces dispersion of electrical properties at the wafer level.

FIG. 12 shows the memory window (MW) measured on a 16 kbit array according to the invention consisting of 16,384 cells operating as a FeRAM with a diameter of 600 nm, each in series with a selection transistor. The memory window is defined in volts and corresponds here to the median memory window (i.e. the median of the distribution of state 1 minus the median of the distribution of state 0). These measurements are therefore statistically relevant.

The addition of a Ti layer between the second TiN conductive layer of the top electrode and the ferroelectric HfO2: Si layer (here 1 nm thick) makes it possible to significantly increase the memory window (by programming/reading at a voltage of 3 V or 4 V, for example) and to reduce the programming/reading voltages, especially compared to a conventional OxRAM memory cell. Thus, the present invention provides a resistive OxRAM memory with improved performance and with possible FeRAM-type operation.

1. A memory array including a plurality of memory cells of a first type, said memory array comprising no other memory cell of a type other than the first type, each of said memory cells of the first type comprising a first electrode, a second electrode and a layer of crystalline active material disposed between the first electrode and the second electrode, the layer of active material having a thickness of between 2 nm and 20 nm, the active material being:
either hafnium dioxide doped with a doping element selected from one of the following elements: Si, Al, Zr, Gd, Ge, Y or N;
or an alloy HfₓZr₁₋ₓO₂ undoped or doped with a doping element selected from one of the following elements: Si, Al, Gd, Ge, Y or N, with 0<X<1;
at least one of said first or second electrodes being formed of at least two layers including:
a first conductive layer in contact with the layer of active material and selected to create oxygen vacancies in the layer of active material;
a second conductive layer disposed on the first conductive layer, a conductive material of the second conductive layer being selected from the following materials: TiN, TaN or W.

2. The array according to claim 1, wherein, in the case of active material of hafnium dioxide doped with a doping element selected from one of the following elements: Si, Al, Zr, Gd, Ge, Y or N, the doping element is present in a percentage of less than or equal to 2% in the active material relative to the total number of atoms in the active material.

3. The array according to claim 1, wherein the layer of crystalline active material is crystallised in an orthorhombic or tetragonal phase.

4. The array according to claim 1, wherein a thickness of the layer of active material is between 2 and 10 nm.

5. The array according to claim 4, wherein the thickness of the layer of active material is substantially equal to 5 nm.

6. The array according to claim 1, wherein the doping element is silicon implanted into the layer of active material and the implantation dose of Si in the layer of active material is between 2.10¹⁴ cm⁻² and 5.10¹⁴ cm⁻².

7. (canceled)

8. The array according to claim 1, wherein a thickness of the first conductive layer is less than or equal to 70% of a thickness of the layer of active material.

9. The array according to claim 8, wherein the thickness of the first conductive layer is less than or equal to 50% of the thickness of the layer of active material.

10. The array according to claim 9, wherein the thickness of the first conductive layer is less than or equal to 50% of the thickness of the layer of active material.

11. The array according to claim 1, wherein each memory cell is connected in series with a selection transistor.

12. The array according to claim 11, wherein said selection transistor is selected to deliver a compliance current passing through the memory cell having an intensity less than or equal to 150 μA.

13. The array according to claim 1, wherein the second conductive layer has a thickness of between 10 nm and 200 nm.

14. The array according to claim 1, wherein the first type of memory cells corresponds to a same nature and a same thickness of the layer of active material.

15. The array according to claim 1, wherein each memory cell is connected in series with a transistor or a selector such as a PN diode or an OTS selector.

16. The array according to claim 4, wherein a thickness of the layer of active material is between 4 and 6 nm.
